(19) United States
(12) Patent Application Publication
(10) Pub. No.: US 2018/0329815 A1
(43) Pub. Date: Nov. 15, 2018

(54) STORAGE SYSTEM AND METHOD FOR NON-VOLATILE MEMORY COMMAND COLLISION AVOIDANCE WITH EXPLICIT TILE GROUPING

(71) Applicant: Western Digital Technologies, Inc., Irvine, CA (US)

(72) Inventors: Seung-hwan Song, San Jose, CA (US); Won Ho Choi, San Jose, CA (US); Chao Sun, San Jose, CA (US); Dejan Vucinic, San Jose, CA (US)

(73) Assignee: Western Digital Technologies, Inc., Irvine, CA (US)

(21) Appl. No.: 15/590,789

(22) Filed: May 9, 2017

(51) Int. Cl. G06F 12/02; G06F 12/0831; G06F 12/127; G06F 13/16; G11C 16/04

(52) U.S. Cl. CPC G06F 12/0246; G06F 12/0833; G06F 12/0215; G11C 8/12; G06F 13/1689; G11C 16/0441; G06F 12/127

(57) ABSTRACT

A storage system is provided comprising a controller and a memory comprising a plurality of tiles of memory organized in a plurality of tile groups, wherein a given tile group is busy when any tile in the given tile group is busy. The controller is configured to: inform the host of the busy status of the plurality of tile groups; receive a plurality of commands from the host, wherein each command is provided with a different tile group identifier of a tile group that is not busy; and execute the plurality of commands, wherein because each command comprises a different tile group identifier of a tile group that is not busy, the plurality of commands are executed in parallel.

### BACKGROUND

Some storage systems have a memory array that is organized into a plurality of tile (subarray) groups, which are designed to only process one read/write command at a time. Accordingly, when a read/write command is being executed in a given tile group, a subsequent read/write command to that tile group cannot be executed until the prior read/write command is completed. In contrast, if a read/write command is sent to a ready tile group, that read/write command can be executed immediately.

### BRIEF DESCRIPTION OF THE DRAWINGS

FIG. 1A is a block diagram of a non-volatile storage system of an embodiment.

FIG. 1B is a block diagram illustrating a storage module of an embodiment.

FIG. 1C is a block diagram illustrating a hierarchical storage system of an embodiment.

FIG. 2A is a block diagram illustrating components of the controller of the non-volatile storage system illustrated in FIG. 1A according to an embodiment.

FIG. 2B is a block diagram illustrating components of the non-volatile memory storage system illustrated in FIG. 1A according to an embodiment.

FIG. 3 is block diagram illustrating a host and storage system of an embodiment.

FIG. 4 is block diagram illustrating a host and storage system of an embodiment during a wear-leveling operation.

FIG. 5 is a flow chart of a method of an embodiment for command collision avoidance.

FIG. 6 is block diagram illustrating a host and storage system of an embodiment, in which the host sends a tile group ID.

FIG. 7 is a graph showing activity of two tile groups.

FIG. 8 is a graph showing activity of two tile groups when a command collision avoidance method of an embodiment is used.

FIG. 9 is block diagram illustrating a host and storage system of an alternate embodiment.

### DETAILED DESCRIPTION

Overview

By way of introduction, the below embodiments relate to a storage system and method for non-volatile memory command collision avoidance with explicit tile grouping. In one embodiment, a storage system is provided comprising a controller and a memory comprising a plurality of tiles of memory organized in a plurality of tile groups, wherein a given tile group is busy when any tile in the given tile group is busy. The controller is configured to: inform the host of the busy status of the plurality of tile groups; receive a plurality of commands from the host, wherein each command is provided with a different tile group identifier of a tile group that is not busy; and execute the plurality of commands, wherein because each command comprises a different tile group identifier of a tile group that is not busy, the plurality of commands are executed in parallel.

In some embodiments, the controller is configured to inform the host of the busy status of the plurality of tile groups by writing a ready/busy indicator for each tile group in one or more host-readable registers in the storage system.

In some embodiments, executing the plurality of commands renders some but not all tiles in at least one tile group busy, and wherein the controller is further configured to perform a background operation in at least one of the tiles in the at least one tile group that is not busy.

In some embodiments, the memory comprises a three-dimensional memory.

In some embodiments, the storage system is embedded in the host.

In some embodiments, the storage system is removably connected to the host.

In another embodiment, a method for command collision avoidance is provided. The method comprises: receiving ready/not ready information of a plurality of memory subarray groups in a storage system, wherein each memory subarray group comprises a plurality of memory subarrays, and wherein a given memory subarray group is not ready if at least one memory subarray in the given memory subarray group is not ready; and sending a plurality of memory access commands to the storage system, wherein each memory access command is sent along with a different memory subarray group ID of a memory subarray group that is ready.

In some embodiments, receiving the ready/not ready information comprises reading the read/not ready information from at least one register in the storage system.

In some embodiments, the method further comprises determining which memory subarray group ID to send along with a given memory access command by using a data structure that associates logical block addresses with memory subarray group IDs.

In some embodiments, the method further comprises determining whether to send a memory access command to a particular memory subarray group ID based on a history of memory access commands sent to the particular memory subarray group ID.

In some embodiments, at least two memory subarray groups have different memory types from one another, and wherein the method further comprises determining which memory subarray group ID to send along with a given memory access command based on the memory type that is appropriate for the given memory access command.

In some embodiments, one memory type has a higher reliability than another other memory type.

In some embodiments, at least one of the plurality of memory subarray groups comprises a three-dimensional memory.

In some embodiments, the receiving and sending are performed by a host in communication with the storage system.

In some embodiments, the storage system is embedded in the host.

In some embodiments, the storage system is removably connected to the host.

In another embodiment, a storage system is provided comprising: a memory; means for providing ready/busy information of a plurality of tile groups in the memory to a host; means for receiving a plurality of commands from the host, wherein each command is associated with a unique tile group identifier of a tile group that is not busy; and means for executing the plurality of commands in parallel.

In some embodiments, at least one of the plurality of tile groups comprises a three-dimensional memory.

In some embodiments, the storage system is embedded in a host.

In some embodiments, the storage system is removably connected to a host.

Other embodiments are possible, and each of the embodiments can be used alone or together in combination. Accordingly, various embodiments will now be described with reference to the attached drawings.

### Embodiments

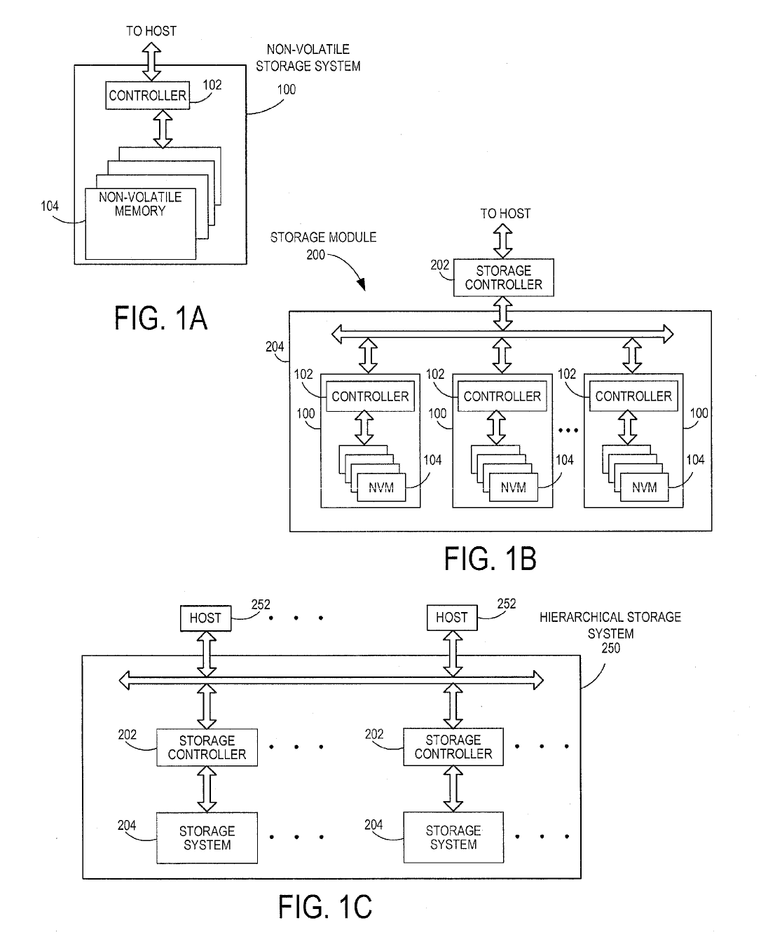

Storage systems suitable for use in implementing aspects of these embodiments are shown in FIGS. 1A-1C. FIG. 1A is a block diagram illustrating a non-volatile storage system 100 according to an embodiment of the subject matter described herein. Referring to FIG. 1A, non-volatile storage system 100 includes a controller 102 and non-volatile memory that may be made up of one or more non-volatile memory die 104. As used herein, the term die refers to the collection of non-volatile memory cells, and associated circuitry for managing the physical operation of those non-volatile memory cells, that are formed on a single semiconductor substrate. Controller 102 interfaces with a host system and transmits command sequences for read, program, and erase operations to non-volatile memory die 104.

The controller 102 (which may be a non-volatile memory controller (e.g., a flash, Re-RAM, PCM, or MRAM controller)) can take the form of processing circuitry, a microprocessor or processor, and a computer-readable medium that stores computer-readable program code (e.g., firmware) executable by the (micro)processor, logic gates, switches, an application specific integrated circuit (ASIC), a programmable logic controller, and an embedded microcontroller, for example. The controller 102 can be configured with hardware and/or firmware to perform the various functions described below and shown in the flow diagrams. Also, some of the components shown as being internal to the controller can also be stored external to the controller, and other components can be used. Additionally, the phrase “operatively in communication with” could mean directly in communication with or indirectly (wired or wireless) in communication with through one or more components, which may or may not be shown or described herein.

As used herein, a non-volatile memory controller is a device that manages data stored on non-volatile memory and communicates with a host, such as a computer or electronic device. A non-volatile memory controller can have various functionality in addition to the specific functionality described herein. For example, the non-volatile memory controller can format the non-volatile memory to ensure the memory is operating properly, map out bad non-volatile memory cells, and allocate spare cells to be substituted for future failed cells. Some part of the spare cells can be used to hold firmware to operate the non-volatile memory controller and implement other features. In operation, when a host needs to read data from or write data to the non-volatile memory, it can communicate with the non-volatile memory controller. If the host provides a logical address to which data is to be read/written, the non-volatile memory controller can convert the logical address received from the host to a physical address in the non-volatile memory. (Alternatively, the host can provide the physical address.) The non-volatile memory controller can also perform various memory management functions, such as, but not limited to, wear leveling (distributing writes to avoid wearing out specific blocks of memory that would otherwise be repeatedly written to) and garbage collection (after a block is full, moving only the valid pages of data to a new block, so the full block can be erased and reused).

Non-volatile memory die 104 may include any suitable non-volatile storage medium, including resistive random-access memory (ReRAM), magnetoresistive random-access memory (MRAM), phase-change memory (PCM), NAND flash memory cells and/or NOR flash memory cells. The memory cells can take the form of solid-state (e.g., flash) memory cells and can be one-time programmable, few-time programmable, or many-time programmable. The memory cells can also be single-level cells (SLC), multiple-level cells (MLC), triple-level cells (TLC), or use other memory cell level technologies, now known or later developed. Also, the memory cells can be fabricated in a two-dimensional or three-dimensional fashion.

The interface between controller 102 and non-volatile memory die 104 may be any suitable flash interface, such as Toggle Mode 200, 400, or 800. In one embodiment, storage system 100 may be a card based system, such as a secure digital (SD) or a micro secure digital (micro-SD) card. In an alternate embodiment, storage system 100 may be part of an embedded storage system.

Although, in the example illustrated in FIG. 1A, non-volatile storage system 100 (sometimes referred to herein as a storage module) includes a single channel between controller 102 and non-volatile memory die 104, the subject matter described herein is not limited to having a single memory channel. For example, in some storage system architectures (such as the ones shown in FIGS. 1B and 1C), 2, 4, 8 or more memory channels may exist between the controller and the memory device, depending on controller capabilities. In any of the embodiments described herein, more than a single channel may exist between the controller and the memory die, even if a single channel is shown in the drawings.

FIG. 1B illustrates a storage module 200 that includes plural non-volatile storage systems 100. As such, storage module 200 may include a storage controller 202 that interfaces with a host and with storage system 204, which includes a plurality of non-volatile storage systems 100. The interface between storage controller 202 and non-volatile storage systems 100 may be a bus interface, such as a serial advanced technology attachment (SATA), peripheral component interface express (PCIe) interface, or dual-date-rate (DDR) interface. Storage module 200, in one embodiment, may be a solid state drive (SSD), or non-volatile dual in-line memory module (NVDIMM), such as found in server PC or portable computing devices, such as laptop computers, and tablet computers.

FIG. 1C is a block diagram illustrating a hierarchical storage system. A hierarchical storage system 250 includes a plurality of storage controllers 202, each of which controls a respective storage system 204. Host systems 252 may access memories within the storage system via a bus interface. In one embodiment, the bus interface may be an NVMe or fiber channel over Ethernet (FCoE) interface. In one embodiment, the system illustrated in FIG. 1C may be a rack mountable mass storage system that is accessible by multiple host computers, such as would be found in a data center or other location where mass storage is needed.

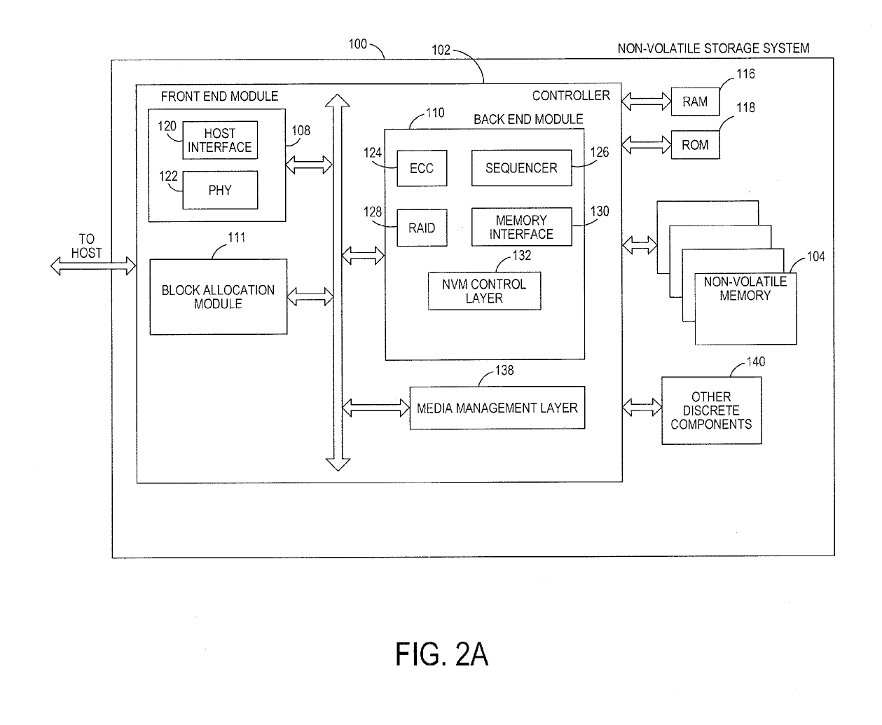

FIG. 2A is a block diagram illustrating components of controller 102 in more detail. Controller 102 includes a front end module 108 that interfaces with a host, a back end module 110 that interfaces with the one or more non-volatile memory die 104, and various other modules that perform functions which will now be described in detail. A module may take the form of a packaged functional hardware unit designed for use with other components, a portion of a program code (e.g., software or firmware) executable by a (micro)processor or processing circuitry that usually performs a particular function of related functions, or a self-contained hardware or software component that interfaces with a larger system, for example. Modules of the controller 102 may include a command collision avoidance module 111, which is discussed in more detail below, and can be implemented in hardware or software/firmware.

Referring again to modules of the controller 102, a buffer manager/bus controller 114 manages buffers in random access memory (RAM) 116 and controls the internal bus arbitration of controller 102. A read only memory (ROM) 118 stores system boot code. Although illustrated in FIG. 2A as located separately from the controller 102, in other embodiments one or both of the RAM 116 and ROM 118 may be located within the controller. In yet other embodiments, portions of RAM and ROM may be located both within the controller 102 and outside the controller.

Front end module 108 includes a host interface 120 and a physical layer interface (PHY) 122 that provide the electrical interface with the host or next level storage controller. The choice of the type of host interface 120 can depend on the type of memory being used. Examples of host interfaces 120 include, but are not limited to, SATA, SATA Express, SAS, Fibre Channel, USB, PCIe, and NVMe. The host interface 120 typically facilitates transfer for data, control signals, and timing signals.

Back end module 110 includes an error correction controller (ECC) engine 124 that encodes the data bytes received from the host, and decodes and error corrects the data bytes read from the non-volatile memory. A command sequencer 126 generates command sequences, such as program and erase command sequences, to be transmitted to non-volatile memory die 104. A RAID (Redundant Array of Independent Drives) module 128 manages generation of RAID parity and recovery of failed data. The RAID parity may be used as an additional level of integrity protection for the data being written into the memory device 104. In some cases, the RAID module 128 may be a part of the ECC engine 124. A memory interface 130 provides the command sequences to non-volatile memory die 104 and receives status information from non-volatile memory die 104. In one embodiment, memory interface 130 may be a double data rate (DDR) interface, such as a Toggle Mode 200, 400, or 800 interface. A flash control layer 132 controls the overall operation of back end module 110.

The storage system 100 also includes other discrete components 140, such as external electrical interfaces, external RAM, resistors, capacitors, or other components that may interface with controller 102. In alternative embodiments, one or more of the physical layer interface 122, RAID module 128, media management layer 138 and buffer management/bus controller 114 are optional components that are not necessary in the controller 102.

FIG. 2B is a block diagram illustrating components of non-volatile memory die 104 in more detail. Non-volatile memory die 104 includes peripheral circuitry 141 and non-volatile memory array 142. Non-volatile memory array 142 includes the non-volatile memory cells used to store data. The non-volatile memory cells may be any suitable non-volatile memory cells, including ReRAM, MRAM, PCM, NAND flash memory cells and/or NOR flash memory cells in a two dimensional and/or three dimensional configuration. Non-volatile memory die 104 further includes a data cache 156 that caches data. Peripheral circuitry 141 includes a state machine 152 that provides status information to the controller 102.

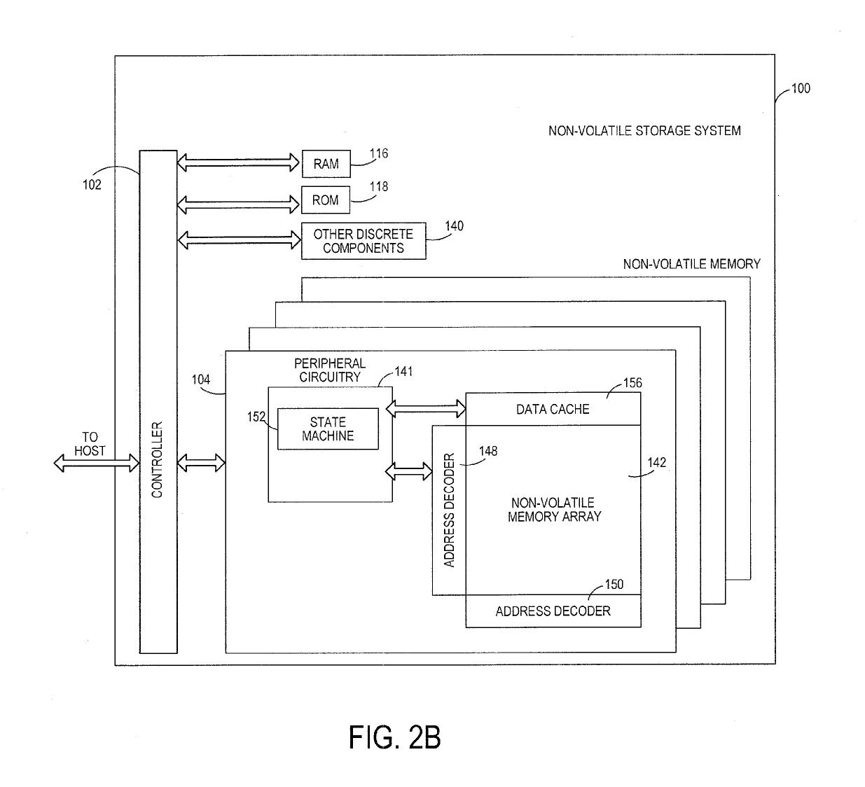

FIG. 3 is an illustration of one particular implementation of an embodiment. It should be noted that this is just an example, and other implementations can be used. FIG. 3 shows a host 50 in communication with some of the components of the storage system 100; namely, the controller 102 and the memory 104. It should be understood that other components of the storage system 100 (including, but not limited to, those components discussed above) can be used and are not shown in FIG. 3 to simplify the drawing. Here, the memory 104 comprises a plurality of non-volatile memory chips (or dies); however, in other embodiments, the memory 104 can contain a single chip/die. FIG. 3 shows one of the memory chips 300 in greater detail. Some or all of the other memory chips can be similarly organized. As shown in FIG. 3, the memory chip 300 in this embodiment comprises a plurality of memory tiles (here, Tile 0 to Tile 16), organized into a plurality of logical tile groups (here, Tile Group A to Tile Group D). As used herein, a memory tile can refer to a memory subarray, and a tile (or subarray) group can refer to a logical grouping of individual memory tiles (or subarrays).

As shown in FIG. 3, in this embodiment, each memory tile/subarray comprises a plurality of bitlines, a plurality of wordlines, a plurality of memory cells at the intersection of the bitlines and wordlines, a plurality of column address decoders, a plurality of wordline drivers (not shown), and a single sense amplifier that is shared by the plurality of bitlines. In this particular embodiment, a memory cell is a two-terminal device at the cross-point of wordlines and bitlines, although other memory cell designs can be used. As shown in FIG. 3, during a read/sense operation of a given memory cell in a tile, there can be some leakage current in other memory cells. Again, because there is a single sense amplifier shared by all the memory cells in a given memory tile, only one memory cell can be read from a given tile at any given time. That is, when non-volatile memory cells of a single tile are written or read, the next read/write commend to the same tile cannot be served until the prior write or read operation is finished due to the physical sharing of the circuitry in the tile (e.g., the sense amplifier). Also, because a write operation is much slower than a read operation, a read/write-after-write sequence on the same tile can be delayed more significantly than read/write-after-read sequence. In contrast, a read/write command would be immediately executed if it accessed an idle tile of the cell array.

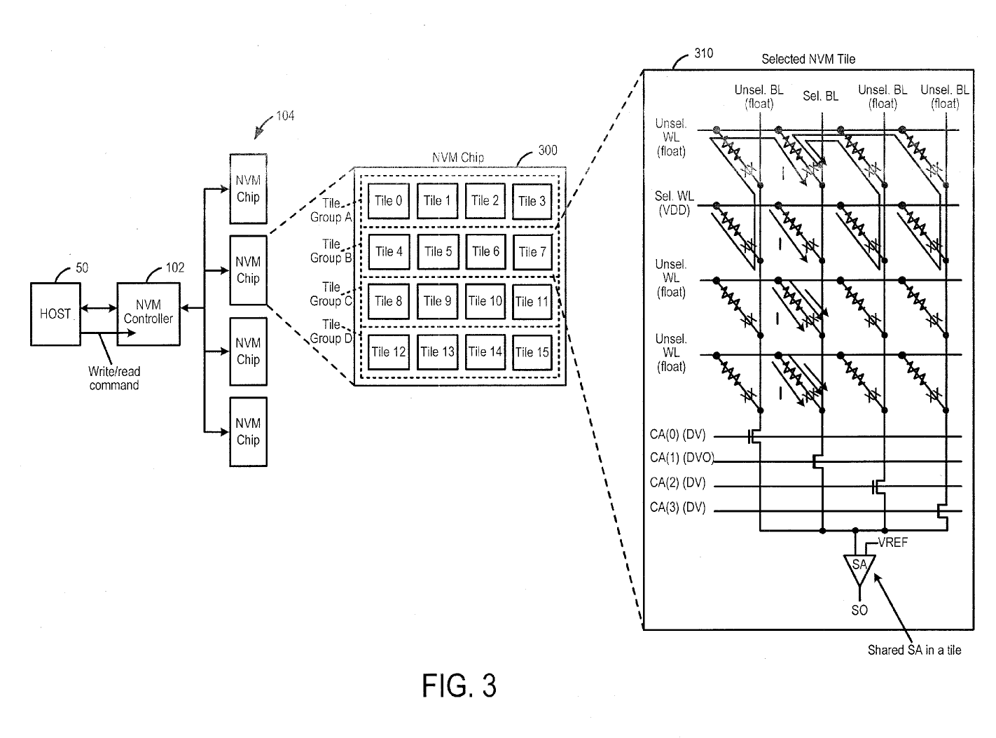

As noted above, in this embodiment, the plurality of memory tiles (here, Tile 0 to Tile 16) are organized into a plurality of logical tile groups (here, Tile Group A to Tile Group D). In this embodiment, the tiles in a logical tile group do not share components (e.g., wordlines, bitlines, column decoders, sense amplifier). That is, each tile in a tile group has its own components and can be operated independently. However, in this embodiment, logical tile groups are used to simplify the communications protocol between the host 50 and the storage system 100. Specifically, since each memory tile can be operated independently, the controller 102 can keep track of the ready/busy status of each of the memory tiles. However, as there can be thousands of memory tiles in a storage system, communicating the ready/busy status of thousands of memory tiles to the host 50 can consume a lot of bandwidth and compromise performance. So, in one embodiment, a logical tile group is used to logically group together two or more tiles. In this organizational framework, a given tile group is considered busy when any tile in the given tile group is busy, and a given tile group is considered ready when all the tiles in the given tile group are ready. Again, this logical abstraction is used to reduce the overhead in managing ready/busy indicators to a smaller group than all the memory tiles, but such convenience comes at the tradeoff of not using ready memory tiles in a tile group that is considered busy. This concept is illustrated in FIG. 4.

FIG. 4 shows the situation where the controller 102 sends a command for wear-leveling (or refresh). Because repeated read/write operations to a memory cell/tile can reduce the memory cell's/tile's ability to reliably retain data (endurance), the controller 102 can implement a wear-level algorithm, in which data is moved around the memory 104 in order to help ensure that the various tiles in the memory 104 are used more equally than if a wear-leveling algorithm was not used. In FIG. 4, the wear-leveling operation causes data to be moved between Tile 1 and Tile 11, which means that both Tile 1 and Tile 11 are busy (e.g., because each tile only has a single sense amp, which is occupied by this operation). Under the tile group abstraction of this embodiment, because Tile 1 and Tile 11 are busy, Tile Groups A and C are also considered busy (because Tile 1 belongs to Tile Group A, and Tile 11 belongs to Tile Group C). This is true even though other tiles in those two groups may be ready (again, this is the “cost” for simplifying the ready/busy management under this abstraction). This means that a read/write command from the host 50 that is mapped to either Tile Group A or Tile Group C needs to wait until the swap operation is complete and Tile Groups A and C are marked as ready.

This problem of a command needing to wait until the tile group is ready is referred to herein as “command collision.” The host 50 can attempt to re-order commands to “schedule around” a collision. However, a host's attempt to avoid a collision by scheduling commands may not be effective, especially in environments where the host 50 does not have information about physical memory tile placement and simply sends a logical block address to the storage system 100 with a read/write command. The controller 102 in the storage system 100 would translate the logical block address from the host 50 to a physical address of a tile or portion thereof. So, the host 50 may not know exactly which tile is idle or not, as the controller 102 hides physical tile placement in the array by internal logical-to-physical mapping for wear-leveling or bad page management. Also, additional write commands for wear-leveling or non-volatile memory cell refresh (read and write) can be issued from the controller 102. So, any host command to the busy tile that is serving the controller 102, as well as host-issued commands, may be delayed. Note that wear-leveling can be triggered by a host write operation or a host read operation making read disturbance. Also, while write-suspension has been proposed for NAND flash, it requires additional hardware resources, such as a write buffer, and may not be possible for certain types of non-volatile memories, such as PCM, RRAM, and MRAM, as suspended write pulses may not guarantee the correct data to be written

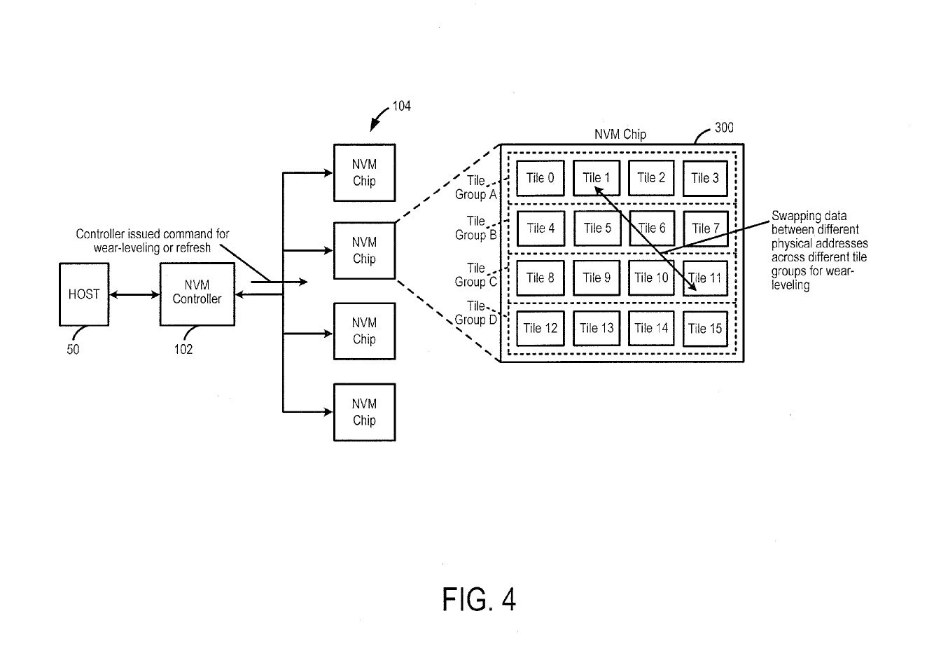

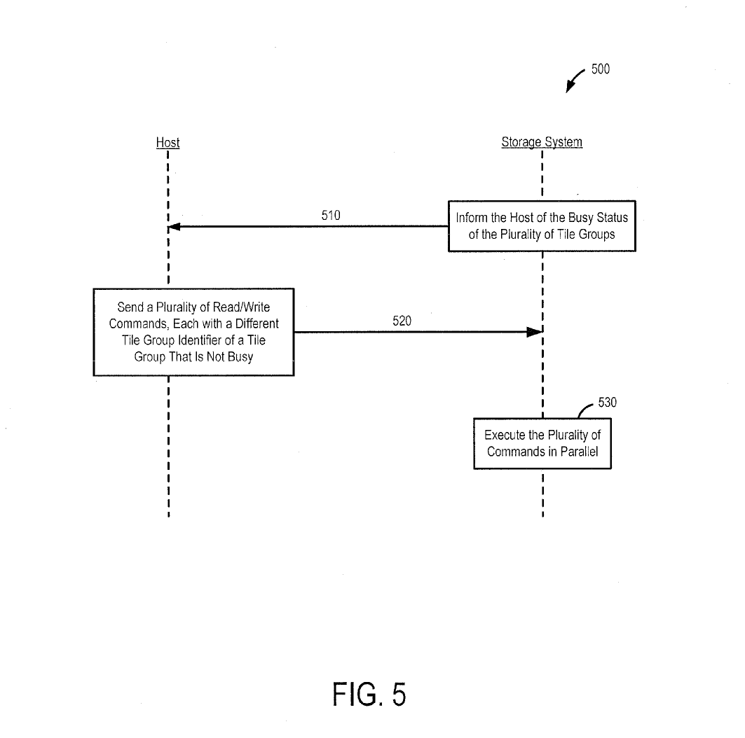

The following embodiments can be used to solve the command collision problem and thereby improve tile latency of a read/write command from the host 50. In general, these embodiments take advantage of the simplified management of ready/busy indicators from using logical tile groupings to report the ready/busy status of each tile group to the host 50. In one embodiment, the host 50 can schedule read/write commands only to ready tile groups, so those commands can be executed in parallel among the ready tile group. That is, by issuing multiple read/write commands having different tile group IDs, each command can be serviced together from different physical tile groups, which provides higher performance under a given power consumption limit. In this way, the host 50 can optimize write/read scheduling by not requesting further memory accesses to the busy tile group. An illustration of this embodiment will now be presented in conjunction with the flow chart 500 in FIG. 5 and the block diagram of FIG. 6.

As shown in FIGS. 5 and 6, in one embodiment, the storage system 100 informs the host 50 of the busy status of the plurality of tile groups (act 510). In providing the busy status of the tile groups, the storage system 100 can affirmatively indicate which tile groups are busy and which tile groups are ready (not busy), or the storage system 100 can just indicate while tile groups are busy, with the host 50 inferring that the tile groups that are not indicated to be busy are ready. The storage system 100 can inform the host 50 of the busy status of the plurality of tile groups in any suitable way. For example, the storage system 100 can inform the host 50 of the busy status by storing the status in the storage system 100 for the host 50 to read. Alternatively, the storage system 100 can send the busy information to the host 50 in some fashion (e.g., periodically, in response to receiving a specific request for the information, after receiving a memory access command to give the host 50 the opportunity to reschedule it, etc.).

In one embodiment, the storage system 100 (e.g., the controller 102, the command collision avoidance module 111, or some other component) writes a ready/busy indicator for each tile group in one or more host-readable registers in the storage system 100. The host 50 can access/poll the register(s) at any appropriate time (e.g., during power-on, during idle time, whenever the memory 104 is to be accessed, etc.). By being in a register, the host 50 can access the information faster than if it were stored in the non-volatile memory 104, assuming that the access time to the register is shorter that the access time to the non-volatile memory 104. Of course, the information can instead be stored in the non-volatile memory 104 or some other component in the storage system 100.

With the information about the busy status of the tile groups, the host 50 will know which tile groups are busy and which tile groups are free and can schedule a plurality of memory access commands to tile groups that are free. In one embodiment, the host 50 contains a table or other data structure that relates logical block addresses (LBAs) with tile group/memory subarray group IDs. With such a data structure, the host 50 can know which tile group ID to include in a memory access request for a particular LBA, in view of the ready/busy information it gets from the storage system 100. In this way, the host 50 can issue a logical tile group ID, which the controller 102 maps to some logical tile group (e.g., Tile Group A, B, C, or D).

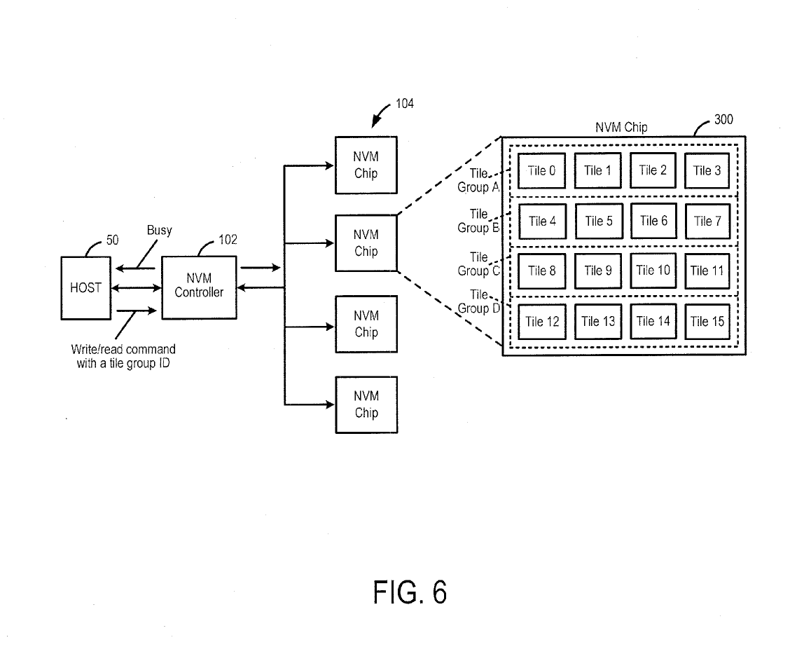

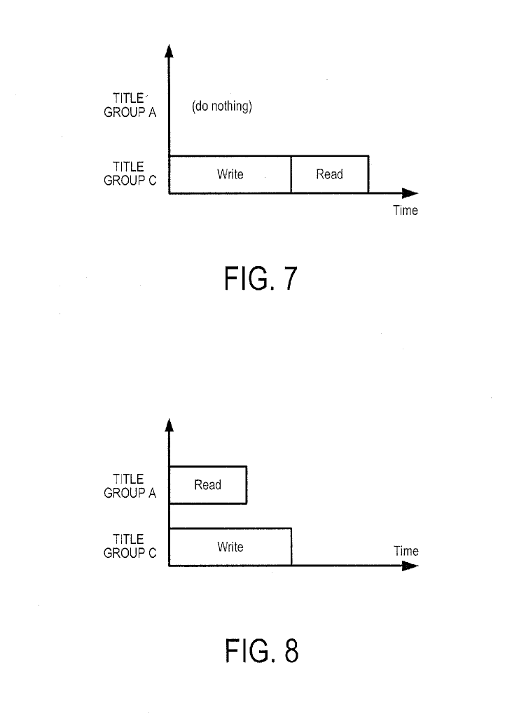

By scheduling a plurality of memory access commands to tile groups that are free, the commands can be immediately executed (in contrast to sending a command to a tile group that is busy, where the command would be executed only after in-progress commands to that tile group are completed). This advantage is shown in the graphs in FIGS. 7 and 8. FIG. 7 shows the situation where the command collision avoidance method of this embodiment is not used. In this example, the host 50 sends a write command followed by a read command. These two commands happen to map to the same tile group (Tile Group C, in this example). So, the read command to Tile Group C needs to wait until the write command to Tile Group C is completed) when the same tile is accessed. All the while, Tile Group A is idle and, thus, a wasted resource.

FIG. 8 shows the situation where the command collision avoidance method of this embodiment is used. In this example, the host 50 knows that Tile Groups A and C are both free (from the ready/busy indicators), so the host 50 sends the write command with an identifier for Tile Group C and the read command with the identifier for Tile Group A. This is shown in act 520 in FIG. 5 (the host 50 sends a plurality of read/write commands, each with a different tile group identifier of a tile group that is not busy). In response, the storage system 100 (e.g., the controller 102) executes the read command in Tile Group A in parallel with the write command in Tile Group C (act 530 in FIG. 5). As shown in comparing FIGS. 7 and 8, with the command collision avoidance method of this embodiment, both Tile Groups A and C are utilized, and no delay occurs in executing the read command. This provides for a more-efficient use of memory resources and avoids the delay in command execution.

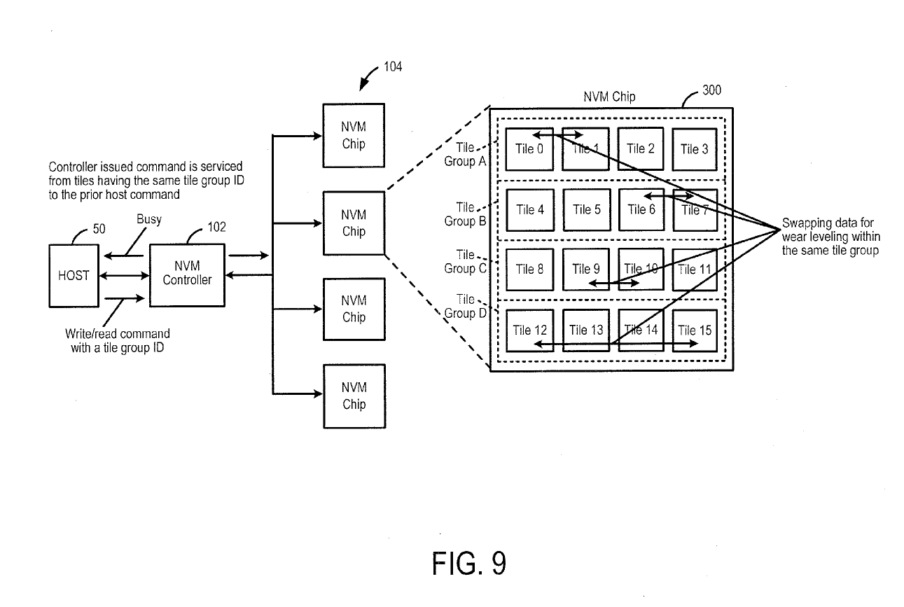

There are many alternatives that can be used with these embodiments. For example, one alternate embodiment takes advantage of the fact that tiles within a tile group can be accessed simultaneously. As explained above, the concept of an entire tile group being considered busy when even one tile in the group is busy is a convenience to avoid the bandwidth and resources needed to report the ready/busy status of all the tiles to the host 50. However, the controller 102 of the storage system 100 will know which tiles it is accessing. So, when a given tile group is designated by the host 50 for a command, the controller 102 will know while tile in the group is being accessed for the host command, and which tiles in the group are free. The controller 102 can then perform background operations in the tiles in the group that are free. This concept is shown in the example presented in FIG. 9. In FIG. 9, the host 50 sends read/write commands to Tile Groups A-D, which are all ready, and the controller 102 executes these commands in Tiles 3, 4, 8, and 13, respectively. The controller 102 knows that the other tiles in each of those groups are free for background operations. So, based on the command history within a tile group, the controller 102 can issue background commands to tiles having the same tile group ID as a prior command from the host 50. In this example, the controller 102 swaps data for a background wear-leveling operation in two free tiles in each group (here, Tiles 0 and 1 (Tile Group A), Tiles 6 and 7 (Tile Group B), Tiles 9 and 10 (Tile Group C), and Tiles 12 and 15 (Tile Group D), respectively).

In another alternative, some or all of the tile groups in the memory 104 can have different memory types (e.g., Tile Group A can have single-level cells (SLC), Tile Group B can have multi-level cells (MLC), Tile Groups C and D can have triple-level cells (TLC)). With such a hybrid configuration, the host 50 can determine which Tile Group is appropriate for a given read/write command. For example, the host 50 can use the TILC tile group for cold data (i.e., data with a relatively-low expected access frequency) and use the SLC tile group for hot data (i.e., data with a relatively-high expected access frequency). As another example, the host 50 can designate more write/read operations to the tile groups having higher reliability, which may be beneficial when the host 50 is responsible for the global management of wear of the memory 104.

In yet another embodiment, the host 50 can send a read/write command along with a particular tile group ID based on a history of read/write commands sent with the particular tile group ID. For example, if the host 50 knows that a particular tile group was accessed a lot, it can assume that the storage system 100 may need to perform a wear-leveling operation in that tile group soon. As such, the host 50 can avoid scheduling a memory access operation to that tile group even thought that tile group is ready/not busy.

Finally, as mentioned above, any suitable type of memory can be used. Semiconductor memory devices include volatile memory devices, such as dynamic random access memory (“DRAM”) or static random access memory (“SRAM”) devices, non-volatile memory devices, such as resistive random access memory (“ReRAM”), electrically erasable programmable read only memory (“EEPROM”), flash memory (which can also be considered a subset of EEPROM), ferroelectric random access memory (“FRAM”), and magnetoresistive random access memory (“MRAM”), and other semiconductor elements capable of storing information. Each type of memory device may have different configurations. For example, flash memory devices may be configured in a NAND or a NOR configuration.

The memory devices can be formed from passive and/or active elements, in any combinations. By way of non-limiting example, passive semiconductor memory elements include ReRAM device elements, which in some embodiments include a resistivity switching storage element, such as an anti-fuse, phase change material, etc., and optionally a steering element, such as a diode, etc. Further by way of non-limiting example, active semiconductor memory elements include EEPROM and flash memory device elements, which in some embodiments include elements containing a charge storage region, such as a floating gate, conductive nanoparticles, or a charge storage dielectric material.

Multiple memory elements may be configured so that they are connected in series or so that each element is individually accessible. By way of non-limiting example, flash memory devices in a NAND configuration (NAND memory) typically contain memory elements connected in series. A NAND memory array may be configured so that the array is composed of multiple strings of memory in which a string is composed of multiple memory elements sharing a single bit line and accessed as a group. Alternatively, memory elements may be configured so that each element is individually accessible, e.g., a NOR memory array. NAND and NOR memory configurations are examples, and memory elements may be otherwise configured.

The semiconductor memory elements located within and/or over a substrate may be arranged in two or three dimensions, such as a two dimensional memory structure or a three dimensional memory structure.

In a two dimensional memory structure, the semiconductor memory elements are arranged in a single plane or a single memory device level. Typically, in a two dimensional memory structure, memory elements are arranged in a plane (e.g., in an x-z direction plane) which extends substantially parallel to a major surface of a substrate that supports the memory elements. The substrate may be a wafer over or in which the layer of the memory elements are formed or it may be a carrier substrate which is attached to the memory elements after they are formed. As a non-limiting example, the substrate may include a semiconductor such as silicon.

The memory elements may be arranged in the single memory device level in an ordered array, such as in a plurality of rows and/or columns. However, the memory elements may be arrayed in non-regular or non-orthogonal configurations. The memory elements may each have two or more electrodes or contact lines, such as bit lines and wordlines.

A three dimensional memory array is arranged so that memory elements occupy multiple planes or multiple memory device levels, thereby forming a structure in three dimensions (i.e., in the x, y and z directions, where the y direction is substantially perpendicular and the x and z directions are substantially parallel to the major surface of the substrate).

As a non-limiting example, a three dimensional memory structure may be vertically arranged as a stack of multiple two dimensional memory device levels. As another non-limiting example, a three dimensional memory array may be arranged as multiple vertical columns (e.g., columns extending substantially perpendicular to the major surface of the substrate, i.e., in the y direction) with each column having multiple memory elements in each column. The columns may be arranged in a two dimensional configuration, e.g., in an x-z plane, resulting in a three dimensional arrangement of memory elements with elements on multiple vertically stacked memory planes. Other configurations of memory elements in three dimensions can also constitute a three dimensional memory array.

By way of non-limiting example, in a three dimensional NAND memory array, the memory elements may be coupled together to form a NAND string within a single horizontal (e.g., x-z) memory device levels. Alternatively, the memory elements may be coupled together to form a vertical NAND string that traverses across multiple horizontal memory device levels. Other three dimensional configurations can be envisioned wherein some NAND strings contain memory elements in a single memory level while other strings contain memory elements which span through multiple memory levels. Three dimensional memory arrays may also be designed in a NOR configuration and in a ReRAM configuration.

Typically, in a monolithic three dimensional memory array, one or more memory device levels are formed above a single substrate. Optionally, the monolithic three dimensional memory array may also have one or more memory layers at least partially within the single substrate. As a non-limiting example, the substrate may include a semiconductor such as silicon. In a monolithic three dimensional array, the layers constituting each memory device level of the array are typically formed on the layers of the underlying memory device levels of the array. However, layers of adjacent memory device levels of a monolithic three dimensional memory array may be shared or have intervening layers between memory device levels.

Then again, two dimensional arrays may be formed separately and then packaged together to form a non-monolithic memory device having multiple layers of memory. For example, non-monolithic stacked memories can be constructed by forming memory levels on separate substrates and then stacking the memory levels atop each other. The substrates may be thinned or removed from the memory device levels before stacking, but as the memory device levels are initially formed over separate substrates, the resulting memory arrays are not monolithic three dimensional memory arrays. Further, multiple two dimensional memory arrays or three dimensional memory arrays (monolithic or non-monolithic) may be formed on separate chips and then packaged together to form a stacked-chip memory device.

Associated circuitry is typically required for operation of the memory elements and for communication with the memory elements. As non-limiting examples, memory devices may have circuitry used for controlling and driving memory elements to accomplish functions such as programming and reading. This associated circuitry may be on the same substrate as the memory elements and/or on a separate substrate. For example, a controller for memory read-write operations may be located on a separate controller chip and/or on the same substrate as the memory elements.

One of skill in the art will recognize that this invention is not limited to the two dimensional and three dimensional structures described but cover all relevant memory structures within the spirit and scope of the invention as described herein and as understood by one of skill in the art.

It is intended that the foregoing detailed description be understood as an illustration of selected forms that the invention can take and not as a definition of the invention. It is only the following claims, including all equivalents, that are intended to define the scope of the claimed invention. Finally, it should be noted that any aspect of any of the embodiments described herein can be used alone or in combination with one another.

What is claimed is:

1. A storage system comprising:
a memory comprising a plurality of tiles of memory organized in a plurality of tile groups, wherein a given tile group is busy when any tile in the given tile group is busy; and
a controller in communication with the memory and with a host, wherein the controller is configured to:
inform the host of the busy status of the plurality of tile groups;
receive a plurality of commands from the host, wherein each command is provided with a different tile group identifier of a tile group that is not busy; and
execute the plurality of commands, wherein because each command comprises a different tile group identifier of a tile group that is not busy, the plurality of commands are executed in parallel.

2. The storage system of claim 1, wherein the controller is configured to inform the host of the busy status of the plurality of tile groups by writing a ready/busy indicator for each tile group in one or more host-readable registers in the storage system.

3. The storage system of claim 1, wherein executing the plurality of commands renders some but not all tiles in at least one tile group busy, and wherein the controller is further configured to perform a background operation in at least one of the tiles in the at least one tile group that is not busy.

4. The storage system of claim 1, wherein the memory comprises a three-dimensional memory.

5. The storage system of claim 1, wherein the storage system is embedded in the host.

6. The storage system of claim 1, wherein the storage system is removably connected to the host.

7. A method for command collision avoidance, the method comprising:
receiving ready/not ready information of a plurality of memory subarray groups in a storage system, wherein each memory subarray group comprises a plurality of memory subarrays, and wherein a given memory subarray group is not ready if at least one memory subarray in the given memory subarray group is not ready; and
sending a plurality of memory access commands to the storage system, wherein each memory access command is sent along with a different memory subarray group ID of a memory subarray group that is ready.

8. The method of claim 7, wherein receiving the ready/not ready information comprises reading the read/not ready information from at least one register in the storage system.

9. The method of claim 7 further comprising determining which memory subarray group ID to send along with a given memory access command by using a data structure that associates logical block addresses with memory subarray group IDs.

10. The method of claim 7 further comprising determining whether to send a memory access command to a particular memory subarray group ID based on a history of memory access commands sent to the particular memory subarray group ID.

11. The method of claim 7, wherein at least two memory subarray groups have different memory types from one another, and wherein the method further comprises determining which memory subarray group ID to send along with a given memory access command based on the memory type that is appropriate for the given memory access command.

12. The method of claim 11 wherein one memory type has a higher reliability than another other memory type.

13. The method of claim 7, wherein at least one of the plurality of memory subarray groups comprises a three-dimensional memory.

14. The method of claim 7, wherein the receiving and sending are performed by a host in communication with the storage system.

15. The method of claim 14, wherein the storage system is embedded in the host.

16. The method of claim 14, wherein the storage system is removably connected to the host.

17. A storage system comprising:
a memory;
means for providing ready/busy information of a plurality of tile groups in the memory to a host;
means for receiving a plurality of commands from the host, wherein each command is associated with a unique tile group identifier of a tile group that is not busy; and
means for executing the plurality of commands in parallel.

18. The storage system of claim 17, wherein at least one of the plurality of tile groups comprises a three-dimensional memory.

19. The storage system of claim 17, wherein the storage system is embedded in a host.

20. The storage system of claim 17, wherein the storage system is removably connected to a host.
